(19) United States
(12) Patent Application Publication
(10) Pub. No.: US 2008/0176408 A1
(43) Pub. Date: Jul. 24, 2008

(54) METHOD AND APPARATUS FOR MANUFACTURING SEMICONDUCTOR DEVICES, CONTROL PROGRAM AND COMPUTER-READABLE STORAGE MEDIUM

(75) Inventors: Akihito TODA, Nirasaki-shi (JP); Hiroki Amemiya, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/967,578

(22) Filed: Dec. 31, 2007

Related U.S. Application Data
(60) Provisional application No. 60/908,699, filed on Mar. 29, 2007.

(30) Foreign Application Priority Data
Jan. 24, 2007 (JP) 2007-013301

(51) Int. Cl. H01L 21/461; H01L 21/306

(52) U.S. Cl. 438/715; 156/345.27; 257/E21.483

(57) ABSTRACT

A method for manufacturing a semiconductor device includes mounting a target substrate on a mounting table in a processing chamber; performing a plasma etching process via a resist mask; and performing an ashing process for removing the resist mask in the same processing chamber. Further, a temperature control of the target substrate is performed to increase the temperature of the target substrate higher than a temperature level in the plasma etching process in the ashing process.

### FIELD OF THE INVENTION

The present invention relates to a semiconductor device manufacturing method and apparatus for performing a plasma etching process and an ashing process in a same processing chamber; and also relates to a control program and a computer-readable storage medium to be used therefor.

### BACKGROUND OF THE INVENTION

Conventionally, in a manufacturing process for a semiconductor device, a plasma etching process is performed via a resist mask to form, e.g., insulating films and the like in a desired pattern. Further, there is known an ashing method for removing the resist mask by using an oxygen gas after the plasma etching process is completed.

Moreover, as for the plasma etching method, there is also known a technique that during the etching process, a target substrate is firmly held on a temperature-controlled mounting table by increasing a voltage applied to an electrostatic chuck, which functions to electrostatically attract and hold the target substrate, to thereby reduce the temperature of the target substrate (see, for example, Japanese Patent Laid-open Application No. H7-335570).

In the above-mentioned manufacturing process of the semiconductor device, it is required to manufacture semiconductor devices with high efficiency by improving productivity. Thus, the present inventors have attempted to develop a way to perform an ashing process for removing a resist mask in a processing chamber in which a plasma etching process of, e.g., an insulating film or the like was previously performed via the resist mask.

However, problems have been found that if the ashing process is performed to remove the resist mask in the same processing chamber in which the plasma etching process of, e.g., the insulating film was previously carried out, there is a possibility that an underlayer such as a metal film, a silicon nitride film or the like is etched unintentionally, resulting in deterioration in the performance of semiconductor devices to be manufactured, and reduction of yield.

### SUMMARY OF THE INVENTION

In view of the foregoing, the present invention provides a method and apparatus capable of manufacturing high-performance semiconductor devices with high efficiency by improving productivity, while increasing a yield thereof by way of preventing an undesired etching of an underlayer. Further, the present invention provides a control program and a computer-readable storage medium to be used therefor.

In accordance with a first aspect of the present invention, there is provided a manufacturing a semiconductor device including: mounting a target substrate on a mounting table in a processing chamber; performing a plasma etching process via a resist mask; and performing an ashing process for removing the resist mask in the same processing chamber, wherein in the ashing process, a temperature control of the target substrate is performed to increase the temperature of the target substrate higher than a temperature level in the plasma etching process.

It is preferable that the temperature control of the target substrate is performed by reducing a pressure of a backside gas supplied between the mounting table and a rear surface of the target substrate.

Alternatively, the temperature control of the target substrate is performed by stopping a supply of a backside gas between the mounting table and a rear surface of the target substrate and creating a vacuum state therein.

It is also preferable that an in-surface uniformity of the ashing process is controlled by individually changing the pressure of the backside gas for each of areas to which the backside gas is supplied.

A silicon dioxide film may be plasma etched in the plasma etching process.

Also, a metal film or a silicon nitride file may be formed under the silicon dioxide film.

In accordance with a second aspect of the present invention, there is provided an apparatus for manufacturing a semiconductor device, including: a processing chamber for accommodating a target substrate therein; a processing gas supply unit for supplying an etching gas and an ashing gas into the processing chamber; a plasma generating unit for generating a plasma of the etching gas or the ashing gas supplied from the processing gas supply unit to process the target substrate; and a control unit for controlling the manufacturing method of the semiconductor device described in the first aspect to be carried out in the processing chamber.

In accordance with a third aspect of the present invention, there is provided a computer-executable control program stored in a storage medium for controlling, when executed, a semiconductor device manufacturing apparatus to perform the semiconductor device manufacturing method described in the first aspect of the invention.

In accordance with a fourth aspect of the present invention, there is provided a computer-readable storage medium stores therein a computer-executable control program, wherein, when executed, the control program controls the semiconductor device manufacturing apparatus to perform the semiconductor device manufacturing method described in the first aspect of the invention.

In accordance with the aspects of the present invention, there can be provided a method and apparatus for manufacturing the semiconductor devices, the control program, and the computer-readable storage medium, wherein production efficiency is improved in comparison with conventional cases, so that the semiconductor devices can be manufactured with a high efficiency; besides, by preventing an undesired an etching of an underlayer, high-performance semiconductor devices can be fabricated, while increasing a yield thereof.

### BRIEF DESCRIPTION OF THE DRAWINGS

The objects and features of the present invention will become apparent from the following description of embodiments given in conjunction with the accompanying drawings, in which:

FIGS. 1A to 1C provide cross sectional views of a semiconductor wafer to which a semiconductor device manufacturing method in accordance with an embodiment of the present invention is applied;

FIG. 2 is a schematic configuration view of a semiconductor device manufacturing apparatus in accordance with the embodiment of the present invention.

### DETAILED DESCRIPTION OF THE EMBODIMENTS

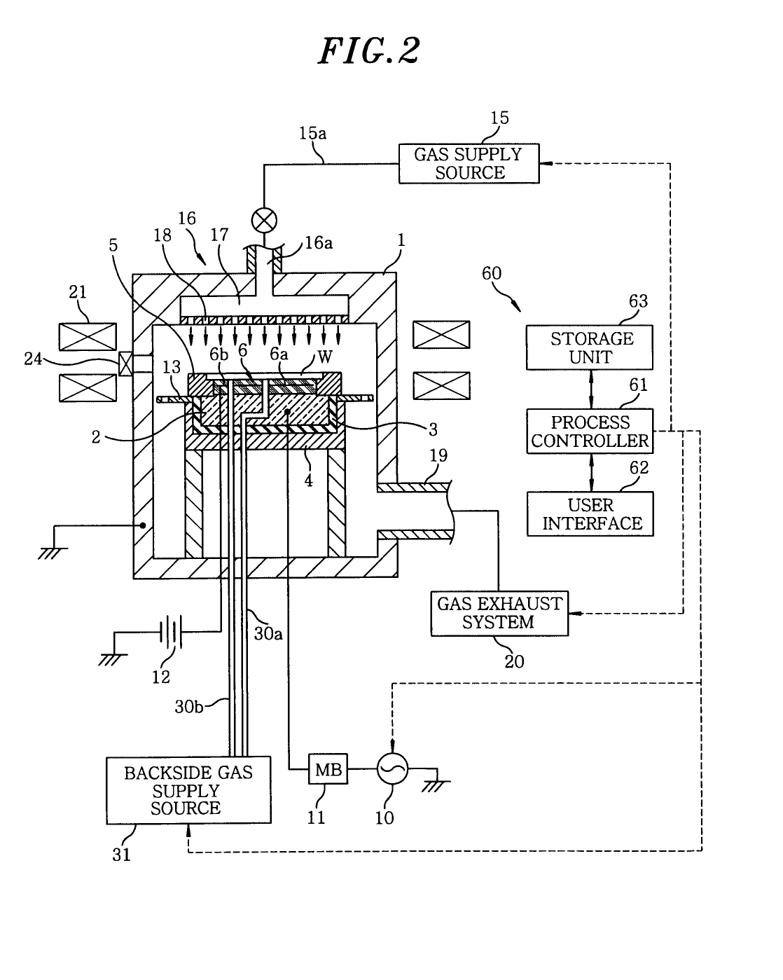

Embodiments of the present invention will be described with reference to the accompanying drawing which form a part hereof. First, the configuration of the plasma processing apparatus will be explained with reference to FIG. 2.

The plasma processing apparatus includes a processing chamber 1 airtightly configured and electrically grounded. The processing chamber 1 has a cylindrical shape and is made of, e.g., aluminum. Disposed in the processing chamber 1 is a mounting table 2 for horizontally sustaining thereon a semiconductor wafer W, which is a target substrate. The mounting table 2, which is made of, e.g., aluminum, is supported by a conductive support 4 via an insulating plate 3. Further, a focus ring 5 formed by, e.g., single-crystalline silicon is disposed on the peripheral portion of the mounting table 2.

An RF power supply 10 is connected to the mounting table 2 via a matching box(MB) 11, and a high frequency power of a specific frequency (e.g., about 13.56 MHz) is supplied from the RF power supply 10 to the mounting table 2. A shower head 16 is disposed above the mounting table 2, while facing the mounting table 2 in parallel. The shower head 16 is grounded. Accordingly, the mounting table 2 and the shower head 16 are configured to function as a pair of electrodes.

An electrostatic chuck 6 for electrostatically attracting and holding the semiconductor wafer W is provided at an upper portion of the mounting table 2. The electrostatic chuck 6 is formed of an insulator 6b and an electrode 6a embedded therein, and the electrode 6a is connected to a DC power supply 12. The semiconductor wafer W is attracted and held by a Coulomb force, which is generated by applying a DC voltage to the electrode 6a from the DC power supply 12.

A coolant path (not shown) is formed inside the mounting table 2, and by circulating a proper coolant through the coolant path, the temperature of the mounting table 2 is regulated at a specific temperature level. Further, backside gas supply channels 30a and 30b for supplying a cold heat transfer gas (backside gas) such as a helium gas or the like to the rear side of the semiconductor wafer W are formed through the mounting table 2 and so forth. These backside gas supply channels 30a and 30b are connected to a backside gas (helium gas) supply source 31.

Specifically, the backside gas supply channel 30a supplies the backside gas to a center portion of the semiconductor wafer W, while the backside gas supply channel 30b supplies the backside gas to a peripheral portion of the semiconductor wafer W. Moreover, it is possible to separately control the pressures of the supplied backsides gas at the center portion and the peripheral portion of the semiconductor wafer W. With these configurations, the semiconductor wafer W held by the electrostatic chuck 6 on the top surface of the mounting table 2 can be regulated to a desired temperature.

Further, a gas exhaust ring 13 is provided outside portion of the focus ring 5. The gas exhaust ring 13 is in contact with the processing chamber 1 via the support 4.

The shower head 16 is disposed at the ceiling portion of the processing chamber 1. The shower head 16 is provided with a number of gas injection openings 18 at its lower surface and has a gas inlet 16a at an upper portion thereof. Further, the shower head 16 has a hollow space 17 formed therein. One end of a gas supply line 15a is connected to the gas inlet 16a, and the other end thereof is connected to a processing gas supply system 15 which supplies a processing gas for etching (etching gas) and a processing gas for ashing (ashing gas).

The processing gas supplied from the processing gas supply system 15 is introduced into the hollow space 17 inside the shower head 16 via the gas supply line 15a and the gas inlet 16a so as to be discharged toward the semiconductor wafer W from the gas injection openings 18.

A gas outlet port 19 is formed at a lower portion of the processing chamber 1, and a gas exhaust system 20 is connected to the gas outlet port 19. By operating a vacuum pump provided in the gas exhaust system 20, the processing chamber 1 can be depressurized to a specific vacuum level. Further, a gate valve 24 for opening and closing a loading/unloading port for the wafer W is provided at a sidewall of the processing chamber 1.

Concentrically disposed around the processing chamber 1 are ring magnets 21 which serve to form a magnetic field in a space between the mounting table 2 and the shower head 16. The ring magnets 21 can be rotated by a rotation mechanism (not shown) such as a motor.

The general operation of the plasma processing apparatus having the above-configuration is controlled by a control unit 60. The control unit 60 includes a process controller 61 having a CPU and controlling each part of the plasma processing apparatus; a user interface 62; and a storage unit 63.

The user interface 62 includes a keyboard for a process manager to input a command to operate the plasma processing apparatus, a display for showing an operational status of the plasma processing apparatus, and the like.

The storage unit 63 stores therein, e.g., recipes including processing condition data and the like and a control program (software) to be used in realizing various processes, which are performed in the plasma processing apparatus under the control of the process controller 61. When a command is received from the user interface 62, a necessary recipe is called from the storage unit 63 and it is executed at the process controller 61. Accordingly, a desired process is performed in the plasma processing apparatus under the control of the process controller 61. The control programs and/or the recipes including the processing condition data and the like can be retrieved from a computer-readable storage medium (e.g., a hard disk, a CD, a flexible disk, a semiconductor memory, and the like), or can be used on-line by being transmitted from another apparatus via, e.g., a dedicated line, whenever necessary.

Below, there will be explained a sequence for plasma etching and plasma ashing a silicon oxide film and the like formed on a semiconductor wafer W by using the plasma processing apparatus configured as described above. First, the gate valve 24 is opened, and a semiconductor wafer W is loaded from a load lock chamber (not shown) into the processing chamber 1 via a transport robot (not shown) or the like, and mounted on the mounting table 2. Then, the transport robot is retreated from the processing chamber 1, and the gate valve 24 is closed. Subsequently, inside of the processing chamber 1 is evacuated via the gas outlet port 19 by the vacuum pump of the gas exhaust system 20.

If the inside of the processing chamber 1 reaches a specific vacuum level, a processing gas (etching gas) is supplied from the processing gas supply system 15 into the processing chamber 1. While maintaining the internal pressure of the processing chamber 1 at a specific pressure level, e.g., about 6.65 Pa (50 mTorr), a high frequency power having a frequency of, e.g., about 13.56 MHz and a power of, e.g., about 100 to 5000 W is supplied to the mounting table 2 from the RF power supply 10. At this time, a specific DC voltage is applied from the DC power supply 12 to the electrode 6a of the electrostatic chuck 6, whereby the semiconductor wafer W is attracted and held by a Coulomb force.

By applying the high frequency power to the mounting table 2 as described above, an electric field is formed between the shower head 16 serving as the upper electrode and the mounting table 2 serving as the lower electrode. Meanwhile, since a horizontal magnetic field is formed at the upper portion of the processing chamber 1 by the presence of the ring magnets 21, electrons are made to drift in the processing space where the semiconductor wafer W is located, which in turn causes a magnetron discharge. As a result of the magnetron discharge, a plasma of the processing gas is generated, and the silicon oxide film and the like formed on the semiconductor wafer W is etched by the plasma. After the etching process is completed, an ashing gas is supplied from the processing gas supply system 15 as a processing gas instead of the etching gas, and an ashing process is performed.

After the above-described etching process and ashing process are completed, the supply of the high frequency power and the processing gas is stopped, and the semiconductor wafer W is unloaded from the processing chamber 1 in a reverse sequence to that described above.

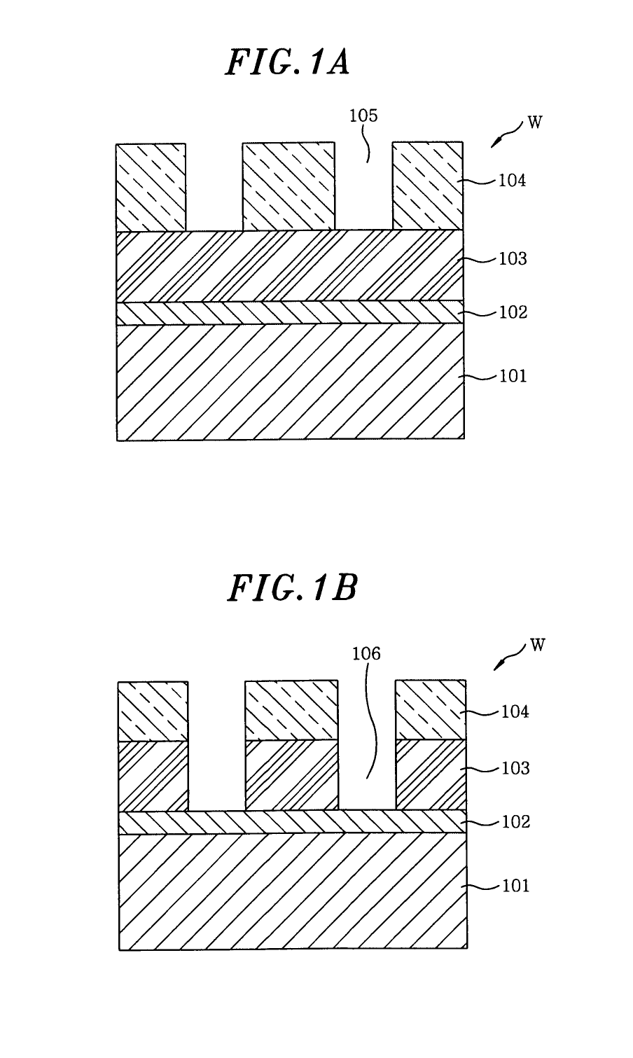

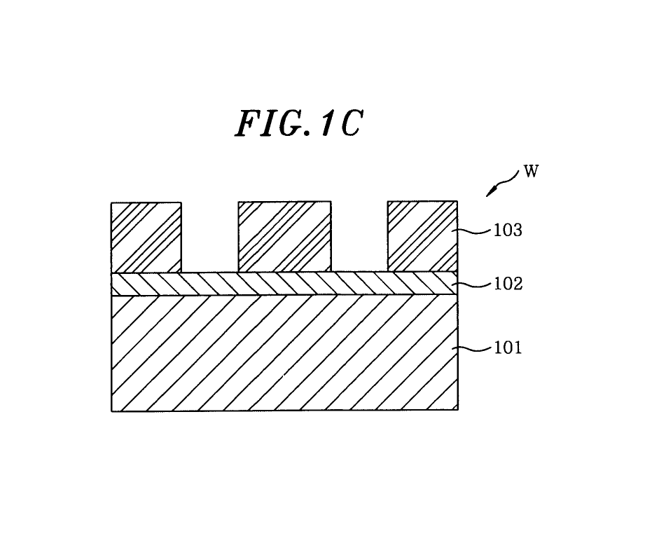

Now, a semiconductor device manufacturing method in accordance with an embodiment of the present invention will be described with reference to FIGS. 1A to 1C. FIGS. 1A to 1C provide enlarged views showing a configuration of major parts of a semiconductor wafer W which is used as a target substrate in the embodiment. In the drawings, reference numeral 101 denotes a silicon substrate forming the semiconductor wafer W. A TiSi film 102 is formed on the silicon substrate 101, and a SiO₂ film 103 is formed on the TiSi film 102 as an insulating film. Further, on the SiO₂ film 103, there is formed a resist mask 104 which has patterned openings 105.

The semiconductor wafer W is loaded into the processing chamber 1 of the apparatus shown in FIG. 2 and is mounted on the mounting table 2. Then, from a state illustrated in FIG. 1A, the SiO₂ film is plasma etched via the resist mask 104, thereby forming holes 106 in the SiO₂ film 103, as shown in FIG. 1B. This plasma etching process is performed by using an etching gas made of, e.g., a gaseous mixture of C₄F₈, Ar and N₂.

Thereafter, while the semiconductor wafer W is still accommodated in the processing chamber 1, ashing of the resist mask 104 is performed from a state shown in FIG. 1B. As a result, the resist mask 104 is removed, as illustrated in FIG. 1C. This ashing process is performed by using, e.g., an ashing gas made of, e.g., a single gas of O₂. Further, in the ashing process, a temperature control is executed to increase the temperature of the semiconductor wafer W higher than that for the plasma etching process. This temperature control can be executed during the ashing process by reducing the gas pressure of a backside gas supplied between the semiconductor wafer W and the mounting table 2 from the backside gas supply source 31 or by stopping the supply of the backside gas. Moreover, in the above description, though the TiSi film 102 is exemplified as an underlayer of the SiO₂ film 103, another metal film such as an aluminum film, a tungsten silicide film or the like can be used, or a silicon nitride film or the like can also be used in lieu of the metal film.

As an example, by using the plasma processing apparatus illustrated in FIG. 2, the above-described plasma etching process and ashing process were performed on a semiconductor wafer having the same structure as shown in FIG. 1A in accordance with a processing recipe specified below.

The processing recipes of the example described below are read from the storage unit 63 of the control unit 60 and inputted to the process controller 61. The process controller 61 controls each part of the plasma processing apparatus based on the control program, whereby the plasma etching process and the ashing process are performed according to the retrieved processing recipes as follows:

### (Processing Recipe for the Plasma Etching)

etching gas: C₄F₈/Ar/N₂=20/500/75 sccm;

pressure: 6.65 Pa (50 mTorr);

high frequency power: 1300 W;

temperature (ceiling and sidewall of chamber/mounting table): 60/20° C.;

backside gas pressure (center/periphery): 1333/1999 Pa (10/15 Torr);

processing time: 194 seconds

### (Processing Recipes for the Plasma Ashing)

ashing gas: O₂=500 sccm;

pressure: 26.6 Pa (200 mTorr);

high frequency power: 300 W;

temperature (ceiling and sidewall of chamber/mounting table): 60/20° C.;

backside gas pressure (center/periphery): 0/0 Pa;

processing time: 60 seconds.

In the above example, the temperature control of the semiconductor wafer W was performed in the ashing process by stopping a supply of the backside gas and setting the backside gas pressure to be zero. After completing the ashing process, the thickness of the underlying TiSi film 102 at the bottom of the holes 106, was measured, and it was found that the thickness of the TiSi film 102 was reduced by average 11.8 nm. Meanwhile, in a comparative example, the ashing process was conducted under the same processing conditions as those for the above example, excepting that the pressure of the backside gas (He gas) was changed to 1333/1999 Pa (10/15 Torr) (center/edge), which pressure levels are the same as those in the etching process. In the comparative example, it was found that an average decrease in the thickness of the underlying TiSi film 102 was 23.5 nm.

As described the above, the decrement in the thickness of the underlying TiSi film 102 of the example was less than ½ of the decrement in thickness of the comparative example. Further, since only the backside gas pressure is changed when the plasma etching process shifts to the ashing process, the change can be made instantaneously, and by changing only the backside gas pressure, the temperature of the semiconductor wafer W during the ashing process can be effectively regulated to be higher than that in the plasma etching process.

Moreover, though the temperature of the mounting table (the temperature of the coolant circulated in the mounting table) was set to be 20° C. as described, the actual temperature of the semiconductor wafer W is several tens of degrees(e.g., about 80° C.) higher than 20° C. because the semiconductor wafer W is exposed to the plasma during the plasma etching process. Further, in the above example, since the pressure level of the backside gas is set to be zero in the plasma ashing process, the actual temperature of the semiconductor wafer W in the ashing process is much higher than the temperature level in the plasma etching process by tens of degrees (e.g., 100° C. or higher).

It is to be noted that changing the temperature of the mounting table (i.e., the temperature of the coolant circulated in the mounting table) itself instead of changing the backside gas pressure to control the wafer temperature is a time-consuming change. Moreover, before starting the processing of a next semiconductor wafer, the temperature of the mounting table (or the coolant in it) needs to be returned to the previous level for the plasma etching, so it is also time-consuming. Thus, if the temperature of the mounting table is changed to control the wafer temperature, production efficiency is deteriorated, resulting in a reduction of throughput.

Furthermore, it is also possible to perform the temperature control of the semiconductor wafer W by some degrees by weakening the attractive force of the electrostatic chuck for attracting the semiconductor wafer W to the mounting table by way of reducing a voltage applied to the electrostatic chuck. In such case, however, an available range of the temperature control is smaller than that in case of adjusting the backside gas pressure. Further, as a result of reducing the attractive force of the electrostatic chuck, there might be incurred a failure to attract and hold the semiconductor wafer W properly.

In contrast, in the present embodiment where the temperature of the semiconductor wafer W is controlled by way of adjusting the backside gas pressure, the adjustment can be done instantaneously, also a temperature control range is wide, and an attraction failure of the semiconductor wafer w is not caused thereby. Further, in the above example, though the pressure of the backside gas is set to be zero both at the center portion and the peripheral portion of the semiconductor wafer W in the ashing process, the backside gas pressure may not be necessarily set as zero; but it can be appropriately changed when the plasma etching process is switched to the ashing process, thus accomplishing the temperature control of the semiconductor wafer W. Moreover, by controlling the backside gas pressure to be different at the center portion and the periphery portion, in-surface uniformity of the ashing process can be adjusted.

The etching of the underlayer during the ashing process in the comparative example is deemed to be due to the deposits or the like which has been attached on the resist mask and released therefrom to act on the underlying film as an etchant. The probability that such etchant acts on the underlayer at the bottom of holes can be lowered by increasing the temperature of the semiconductor wafer W in the ashing process, thus suppressing decrement in the thickness of the underlying film.

As described above, in accordance with the present embodiment, by performing the ashing process after the etching process in the same processing chamber, production efficiency can be higher in comparison with conventional cases, so that semiconductor devices can be manufactured with a higher throughput. Besides, since undesired etching of underlayer can be reduced or prevented, high-performance semiconductor devices can be fabricated, while increasing a yield thereof.

Furthermore, it is to be noted that the present invention is not limited to the embodiment and the example described above, but can be modified in various ways. For example, the plasma processing apparatus is not limited to the parallel plate type apparatus shown in FIG. 2 in which a single frequency power is applied to the lower electrode but various other plasma processing apparatuses can be used instead. For instance, the plasma etching apparatus can be of a type in which dual high frequency powers are applied to the upper and the lower electrode separately or of a type in which dual frequency powers are applied both to the lower electrode only. Beside those exemplified here, various other plasma processing apparatuses can be used.

While the invention has been shown and described with respect to the embodiments, it will be understood by those skilled in the art that various changes and modifications may be made without departing from the scope of the invention as defined in the following claims.

What is claimed is:

1. A method for manufacturing a semiconductor device, comprising:
mounting a target substrate on a mounting table in a processing chamber;
performing a plasma etching process via a resist mask; and then
performing an ashing process that removes the resist mask in the processing chamber,
wherein in the ashing process, a temperature control of the target substrate is performed to increase the temperature of the target substrate higher than that in the plasma etching process.

2. The method of claim 1, wherein the temperature control of the target substrate is performed by reducing a pressure of a backside gas supplied between the mounting table and a rear surface of the target substrate.

3. The method of claim 1, wherein the temperature control of the target substrate is performed by stopping a supply of a backside gas between the mounting table and a rear surface of the target substrate and creating a vacuum state therebetween.

4. The method of claim 2, wherein an in-surface uniformity of the ashing process is controlled by individually changing the pressure of the backside gas for each of areas to which the backside gas is separately supplied.

5. The method of claim 2, wherein a silicon oxide film is plasma etched in the plasma etching process.

6. The method of claim 3, wherein a silicon oxide film is plasma etched in the plasma etching process.

7. The method of claim 5, wherein a metal film or a silicon nitride film is formed under the silicon oxide film.

8. The method of claim 6, wherein a metal film or a silicon nitride film is formed under the silicon oxide film.

9. An apparatus for manufacturing a semiconductor device, comprising:
a processing chamber for accommodating a target substrate therein;
a processing gas supply unit for supplying an etching gas or an ashing gas into the processing chamber;
a plasma generating unit for generating a plasma of the etching or the ashing gas supplied from the processing gas supply unit to process the target substrate; and
a control unit for controlling the semiconductor device manufacturing method described in claim 2 to be carried out in the processing chamber.

10. A computer-executable control program stored in a storage medium for controlling, when executed, a semiconductor device manufacturing apparatus to perform the semiconductor device manufacturing method described in claim 2.

11. A computer-readable storage medium for storing therein a computer-executable control program, wherein, when executed, the control program controls a semiconductor device manufacturing apparatus to perform the semiconductor device manufacturing method described in claim 2.
